(19) United States
(12) Patent Application Publication
(10) Pub. No.: US 2017/0084606 A1
(43) Pub. Date: Mar. 23, 2017

(54) Integrated Circuit with a Plurality of Transistors and at Least One Voltage Limiting Structure

(71) Applicant: Infineon Technologies Austria AG, Villach (AT)

(72) Inventors: Andreas Meiser, Sauerlach (DE); Dirk Priefert, Moers (DE); Rolf Weis, Dresden (DE)

(21) Appl. No.: 15/273,352

(22) Filed: Sep. 22, 2016

(30) Foreign Application Priority Data
Sep. 23, 2015 (DE) 102015116099.4

(51) Int. Cl. H01L 27/02; H01L 27/12; H01L 29/423

(52) U.S. Cl. CPC H01L 27/0296; H01L 27/0255; H01L 27/0292; H01L 29/4236; H01L 27/1207; H01L 29/866

(57) ABSTRACT

An integrated circuit includes a semiconductor body with a first semiconductor layer, an insulation layer on the first semiconductor layer, and a second semiconductor layer on the insulation layer. The integrated circuit further includes a plurality of transistors each including a load path and a control node The load paths are connected in series, and the plurality of transistors are at least partially integrated in the second semiconductor layer. A voltage limiting structure is connected in parallel with the load path of one of the plurality of transistors, wherein the voltage limiting structure is integrated in the first semiconductor layer and is connected to the one of the plurality of transistors through two electrically conducting vias extending through the insulation layer.

### TECHNICAL FIELD

This disclosure in general relates to an integrated circuit including a plurality of transistor device having their load paths connected in series, and at least one voltage limiting structure connected in parallel with the load path of one transistor device.

### BACKGROUND

Transistors, such as MOSFETs (Metal Oxide Field-Effect Transistors), are widely used in automotive, industrial, or consumer electronic applications for driving loads, converting power, or the like. Those transistors are often referred to as power transistors. According to one design concept, the functionality of one power transistor can be obtained by an electronic circuit (transistor arrangement) that includes a plurality of transistor devices that have their load paths connected in series. In this design, voltage limiting structures may be connected in parallel with the load paths of at least some of these transistor devices. These voltage limiting structures, in a blocking state of the transistor arrangement, prevent the individual transistor devices from being overloaded. Furthermore, the voltage limiting structures ensure that an overall voltage applied to the transistor arrangement in the blocking state is more equally shared by the plurality of transistor devices.

There is a need to implement such a transistor arrangement in a space saving manner.

### SUMMARY

One embodiment relates to an integrated circuit. The integrated circuit includes a semiconductor body with a first semiconductor layer, an insulation layer on the first semiconductor layer, and a second semiconductor layer on the insulation layer. The integrated circuit further includes a plurality of transistors each including a load path and a control node. The load paths are connected in series, and the plurality of transistors are at least partially integrated in the second semiconductor layer. A voltage limiting structure is connected in parallel with the load path of one of the plurality of transistors, wherein the voltage limiting structure is integrated in the first semiconductor layer and is connected to the one of the plurality of transistors through two electrically conducting vias extending through the insulation layer.

Those skilled in the art will recognize additional features and advantages upon reading the following detailed description, and upon viewing the accompanying drawings.

### BRIEF DESCRIPTION OF THE DRAWINGS

Examples are explained below with reference to the drawings. The drawings serve to illustrate certain principles, so that only aspects necessary for understanding these principles are illustrated. The drawings are not to scale. In the drawings the same reference characters denote like features.

FIG. 1 schematically illustrates an integrated circuit with a plurality of transistors, according to one embodiment;

FIG. 2 schematically illustrates an integrated circuit with a plurality of transistors, according to another embodiment;

FIGS. 3A-3B show a perspective sectional view and a vertical cross sectional view of one of the plurality of transistors, according to one embodiment;

FIGS. 4A-4C show a perspective sectional view and two vertical cross sectional views of one of the plurality of transistors, according to one embodiment;

FIG. 5 shows a top view of one of the plurality of transistors, according to one embodiment;

FIG. 6 shows a vertical cross sectional view of one of the plurality of transistors, according to one embodiment; and

FIGS. 7A-7B show a vertical cross sectional view and a top view of an integrated circuit according to one example.

### DETAILED DESCRIPTION

In the following detailed description, reference is made to the accompanying drawings. The drawings form a part of the description and by way of illustration show specific embodiments in which the invention may be practised. It is to be understood that the features of the various embodiments described herein may be combined with each other, unless specifically noted otherwise.

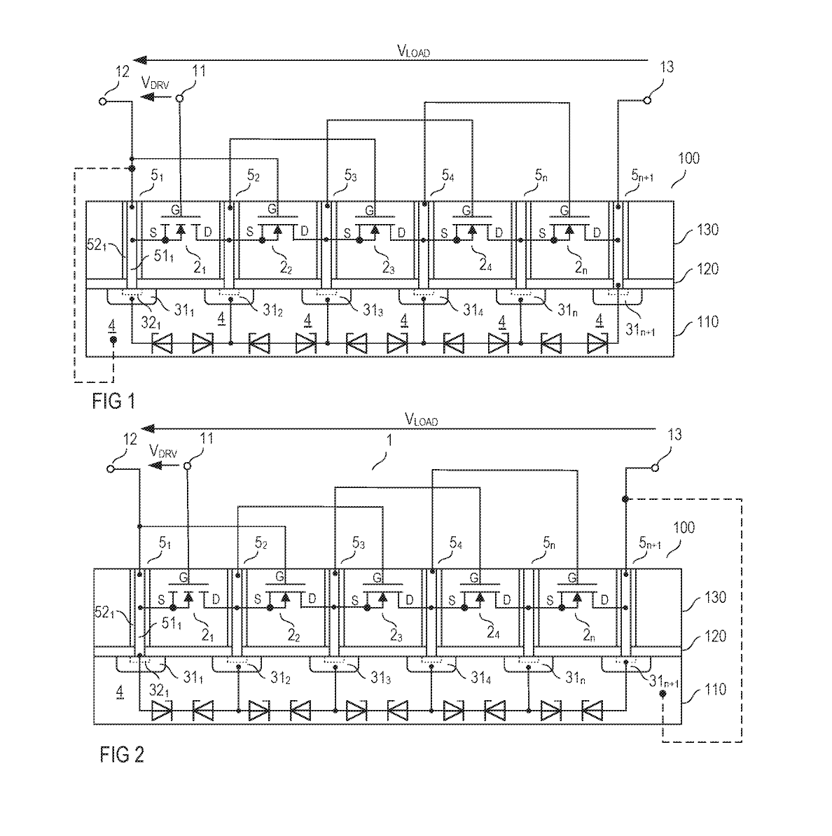

FIG. 1 shows a vertical cross sectional view of an integrated circuit according to one embodiment. The integrated circuit includes a semiconductor body 100 with a first semiconductor layer 110, an insulation layer 120 on the first semiconductor layer 110, and a second semiconductor layer 130 on the insulation layer 120. A semiconductor body 100 of this type may be referred to as SOI (silicon on insulator) substrate. However, the first and second semiconductor layers 110, 130 are not restricted to be silicon layers. Instead, any conventional semiconductor material may be used to implement these semiconductor layers 110, 130. Examples of such semiconductor material includes, but are not restricted, silicon carbide (SiC), arsenide (GaAs), gallium nitride (GaN), silicon or germanium containing materials, or the like. Furthermore, the insulation layer 120 is not restricted to be made of a semiconductor oxide, such as silicon oxide (SiO₂). Instead, any other type of electrically or dielectrically insulating material may be used as well.

The first semiconductor layer 110 and the second semiconductor layer 130 may include the same type of semiconductor material. For example, both, the first semiconductor layer 110 and the second semiconductor layer 130 include monocrystalline silicon. According to another embodiment, the first semiconductor layer 110 and the second semiconductor layer 130 include different types of semiconductor material. According to one embodiment, one of these first and second semiconductor layers 110, 130 includes monocrystalline silicon, and the other one of the first and second semiconductor layers 110, 130 includes monocrystalline silicon carbide.

Referring to FIG. 1, the integrated circuit further includes a plurality of transistors 2₁-2ₙ. In FIG. 1, these transistors 2₁-2ₙ are schematically illustrated by way of circuit symbols. Embodiments of how these transistors may be implemented are explained in greater detail herein further below. These transistors 2₁-2ₙ each are at least partially integrated in the second semiconductor layer 130. “At least partially integrated” means that at least active semiconductor regions of these transistors 2₁-2ₙ are integrated in the second semiconductor layer 130. In the embodiment shown in FIG. 1, the transistors 2₁-2ₙ are drawn as MOSFETs (Metal Oxide Semiconductor Field-Effect Transistors). In this case, active device regions are source regions, body regions, drift regions and drain regions, which is explained in further detail herein below.

Each of the plurality of transistor devices 2₁-2ₙ includes a load path between a first load node D and a second load node S. In the transistor device shown in FIG. 1, the first load node is a drain node, and the second load node is a source node of the respective transistor. Thus, the load paths of the individual transistors 2₁-2ₙ will also be referred to as drain-source paths of these transistors 2₁-2ₙ in the following. The load paths D-S of the transistors 2₁-2ₙ are connected in series, whereas a series circuit with these load paths is connected between a first load node 12 and a second load node 13 of the integrated circuit. Furthermore, each of the plurality of transistors 2₁-2ₙ includes a control node. In the embodiment shown in FIG. 1, the control node is gate node G of the respective MOSFET 2₁-2ₙ.

Referring to FIG. 1, the integrated circuit further includes at least one voltage limiting structure. In this specific embodiment shown in FIG. 1, the integrated circuit includes a plurality of voltage limiting structures such that each of the plurality of transistors 2₁-2ₙ has a voltage limiting structure associated thereto.

The first semiconductor layer 110 has a basic doping of a first doping type (conductivity type) A region of the first semiconductor layer 110 that has the basic doping of the first doping type is labeled with reference character 4 in FIG. 1. This region 4 will be referred to as first region in the following. The voltage limiting structures are formed by the first region 4 and by a plurality of second regions 31₁-31ₙ₊₁ of a second doping type complementary to the first doping type, with each of these second regions 31₁-31ₙ₊₁ being electrically connected to one of a plurality of vias 5₁-5ₙ₊₁. According to one embodiment, each of the vias 5₁-5ₙ₊₁is ohmically connected to the respective second region 31₁-31ₙ₊₁. For this, the individual second regions 3₁-3ₙ₊₁may include contact regions (illustrated in dotted lines in FIG. 1 and labeled with reference character 32₁ in case of second region 31₁) that have a higher doping concentration than the second regions 31₁-31ₙ₊₁ and serve to ohmically connect the second regions 31₁-31ₙ₊₁ to the vias 5₁-5ₙ₊₁.

Each of these voltage limiting structure can be considered as a series circuit with two Avalanche diodes or Zener diodes connected in a back-to-back configuration. The maximum voltage that can be applied between the two vias associated with one voltage limiting structure is substantially given by the breakthrough voltage of that Zener or Avalanche diode that is reverse biased in the series circuit. If a voltage higher than this breakthrough voltage is applied the respective Zener or Avalanche diode conducts and therefore clamps the voltage between the vias. Circuit symbols of those diodes are also shown in FIG. 1. Just for the purpose of illustration, the diodes shown in Figure represent a situation where the first region 4 is p-doped and the second regions are n-doped so that cathodes of the Avalanche or Zener diodes are formed by the second regions 31₁-31₂ and anodes are formed by the first region 4. Although FIG. 1 shows a voltage limiting structure associated with each of the transistors 2₁-2ₙ, this is only an example. The integrated circuit may include an arbitrary number between 1 and n of voltage limiting structures, where n denotes the overall number of transistors 2₁-2ₙ in the series circuit. In the embodiment shown in FIG. 1, the at least one voltage limiting structure is connected in parallel with the load path of the associated transistor 2ᵢ, whereas 2ᵢ denotes an arbitrary transistor of the plurality of transistors 2₁-2ₙ.

In each case, the voltage limiting structure is connected in parallel with the load path of the associated transistor 2ᵢ through two electrically conducting vias extending through the insulation layer 120. Each via extends to or into the first semiconductor layer 110. In the embodiment shown in FIG. 1, where a voltage limiting structure is connected in parallel with the load path of each of the plurality of transistors 2₁-2ₙ, there are n+1 vias 5₁-5ₙ₋₁ to connect the n voltage limiting structures in parallel with the load paths of the n transistors. From these vias 5₁-5ₙ₊₁n−1 vias, which are vias 5₂-5ₙ in the embodiment shown in FIG. 1, are shared by two voltage limiting structures. For example, via 5₂ is one of two vias (the other one is via 5₁) that serve to connect a voltage limiting structure in parallel with the load path of transistor device 2₁. And via 5₂ is one of two vias (the other one is via 5₃) that serves to connect a voltage limiting structure in parallel with the load path of transistor 2₂.

In the present embodiment, each of the vias 5₁-5ₙ₊₁includes an electrically conducting core 51₁ and a collar 52₁ that electrically insulates and separates the core from the second semiconductor layer 130. For the sake of clarity, FIG. 1 shows reference characters only for the core 51₁ and the collar 52₁ of a first via 5₁.

Referring to the above, the load paths of the transistors 2₁-2ₙ are connected in series, whereas the load path of each transistor is connected between two of the plurality of vias 5₁-5ₙ₊₁. Such connecting of each load path between two vias is only schematically illustrated in FIG. 1.

The integrated circuit 1 with the plurality of transistors 2₁-2ₙ operates like one transistor. For this, one 2₁ of the plurality of transistors 2₁-2ₙ is configured to receive an external drive signal V_{DRV} while each of the other transistors receives as a drive signal (drive voltage) a load path voltage of at least one other transistor. For this, the gate node G of the first transistor 2₁ is connected to an input node 11, whereas the external drive signal V_{DRV} can be applied between the input node 11 and the first load node 12 of the integrated circuit. The first transistor 2₁ switches on or off dependent on a voltage level of this drive voltage V_{DRV}. Just for the purpose of illustration, the first transistor 2₁ is drawn as an n-type enhancement MOSFET in the embodiment shown in FIG. 1. A first transistor of this type switches on, when a voltage level of the drive voltage V_{DRV} is above a positive threshold voltage, and switches off when the voltage level of the drive voltage V_{DRV} is below this positive threshold voltage. If the first transistor 2₁ is implemented as an n-type depletion MOSFET instead of an n-type enhancement MOSFET, it switches on when a voltage level of the drive voltage V_{DRV} is above a negative threshold voltage, and switches off when the voltage level is below the negative threshold voltage.

Each of the other transistors, that is, transistors 2₂-2ₙ in the embodiment shown in FIG. 1, is controlled by at least one of the plurality of transistors 2₁-2ₙ. In particular, each of the other transistors 2₂-2ₙ is controlled by a load path voltage of at least one of the plurality of transistors 2₁-2ₙ, In the embodiment shown in FIG. 1, each of these other transistors 2₂-2ₙ is controlled by a load-path voltage of exactly one of the plurality of transistors. The “load-path voltage” of one transistor 2ᵢ is the voltage between the first and second load nodes (drain and source nodes) of the respective transistor 2ᵢ. In the embodiment shown in FIG. 1, transistor 2₂, which is directly connected to the first transistor 2₁, is controlled by the load path voltage of the first transistor 2₁. For this, the gate node G of the transistor 22 is connected to the source node S of the first transistor 2₁. Thus, a drive voltage, which is a voltage between the gate node G and the source node S of the transistor 2₂, equals the negative load path voltage, Which is the voltage between the drain node D and the source node S of the first transistor 2₁. A transistor 2₃, which is the transistor directly connected to transistor 2₂, receives as a drive voltage a load path voltage of the transistor 2₂. For this, the gate node G of the transistor 2₃ is connected to the source node of transistor 2₂. In general, let 2ᵢ be an arbitrary one of the other transistors 2₂-2ₙ. Then, transistor 2ᵢ is controlled by the negative load path voltage of transistor 2ᵢ₋₁. For this, the gate node G of transistor 2ᵢ is connected to the source node of transistor 2ᵢ₋₁.

It should be noted that controlling each of transistors 2₂-2ₙ by the load path voltage of exactly one transistor (transistor 2ᵢ₋₁ in the embodiment shown in FIG. 1) is only an example. According to another embodiment (not shown) at least one of the transistors (such as one of transistors 2₃-2ₙ) receives as a drive voltage a sum of the load path voltages of two or more transistors. In each case, the gate node G of each of the transistors 2₁-2ₙ is connected to the source node of another transistor. That is, the gate node G of one transistor is not connected to the source node S of this transistor.

The way of operation of the integrated circuit shown in FIG. 1 is explained in the following. For the purpose of explanation it is assumed that the first transistor 2₁ is an n-type enhancement MOSFET and that the other transistors 2₂-2ₙ are n-type depletion MOSFETs. For the purpose of explanation it is further assumed that a load voltage V_{LOAD} is applied to the second load node 13 and the first load node 12 of the integrated circuit, that is, between the drain node D of transistor 2ₙ and the source node S of the first transistor 2₁.

The integrated circuit 1 is in an on-state, in which it is capable of conducting an electrical current between the first and second load nodes 12, 13, when the drive voltage V_{DRV} between the input node 11 and the first load node 12 has a voltage level that switches on the first transistor 2₁. In the on-state of the first transistor 2₁, a voltage level of the load path voltage of the first transistor 2₁ is too low to switch off (pinch off) transistor 2₂, so that transistor 2₂ is in the on-state. In the on-state of the transistor 2₂, a voltage level of the load path voltage of the transistor 2₂ is too low to switch off transistor 2₃, so that transistor 2₃ is in the on-state, and so on. Thus, when the first transistor 2₁ is in the on-state, the other transistors 2₂-2ₙ are “automatically” in the on-state, so that the integrated circuit 1 is in the on-state.

When the drive voltage V_{DRV} has a voltage level that switches off first transistor 2₁, a voltage level of the load path voltage of the first transistor 2₁ increases until it reaches a voltage level that switches off the transistor 2₂. When the transistor 2₂ switches off, a voltage level of its load path voltage increases until it reaches a voltage level that switches off transistor 2₃, and so on. In the off-state of the individual transistor, the voltage limiting structures limit voltage levels of the load path voltages so as to more equally distribute the overall load voltage V_{LOAD} to the individual transistors 2₁-2ₙ. It should be noted that in the off-state of the integrated circuit 1, not necessarily each of the transistors 2₁-2ₙ is in the off-state. The number of transistors that are in the off-state is dependent on the overall load voltage V_{LOAD} and the voltage each of the transistors sustains in the off-state, whereas the voltage sustained by each transistor 2₁-2ₙ is limited by the respective voltage limiting structure.

By implementing the transistors 2₁-2ₙ in the second semiconductor layer 130 and implementing the voltage limiting structures in the first semiconductor layer 110 below the second semiconductor layer 130, the overall integrated circuit 1 can be implemented in a very space-saving the manner. Furthermore, the insulation layer 120 can be made relatively thin, which saves cost. In particular, the insulation layer can be implemented such that the dielectric strength is less than the voltage blocking capability of the integrated circuit, wherein the “voltage blocking capability” of the integrated circuit equals the maximum voltage level of a voltage between the drain node D and the source node S the integrated circuit can withstand. This is explained below

For example, if transistor 2ᵢ is blocking (wherein 2ᵢ denotes any one of the transistors 2₁-2ₙ; 31ᵢ₊₁, 31ᵢ denote the associated second regions, and 5ᵢ₊₁, 5ᵢ denote the associated vias) there is a voltage drop between the drain node D and the source node S of the transistor 2ᵢ. The same voltage drops between the second region 31ᵢ₊₁ and the second region 31ᵢ associated with transistor 2ᵢ so that a depletion region (space charge region) expands in the first region 4 between the second regions 31ᵢ₊₁, 31ᵢ. By virtue of this depletion region an electrical potential along the insulation layer 120 decreases between the second region 31ᵢ₊₁ and the second region 31ᵢ from a level that equals drain potential to a level that equals source potential. “Drain potential” is the electrical potential at the drain node D of transistor 2ᵢ and via 5ᵢ₊₁, and “source potential” is the electrical at the source node S and via 5_{i.} In the semiconductor region that is arranged between the vias 5ᵢ₊₁ and 5ᵢ and above the insulation layer 120 the electrical potential decreases substantially in the same way as in the first layer 110 below the insulation layer so that there is only a low voltage drop across the insulation layer 120. The latter makes it possible to implement the insulation layer with a low thickness. For example, the thickness is less than 1 μm.

According to one example, the first region 4 is electrically connected to one of the first and second load nodes 11, 12. For example, if the first region 4 is p-doped and the second regions 31₁-31ₙ₊₁ are n-doped (as shown in FIG. 1), of the first and second load nodes 12, 13 the load node that is connected to the first semiconductor layer 100 is the one with the lower electrical potential. Thus, pn-junctions between the second regions 31₁-31ₙ and the first region 4 are reverse biased and a current flow from the vias 5₁-5ₙ₊₁ into the first semiconductor layer 110 is prevented. For example, if the transistors 2₁-2ₙ are n-type transistor devices, in operation of the integrated structure, the first load node 12 has the lower electrical potential and, therefore, is connected to the first region 4. Such connection is schematically illustrated in dashed lines in FIG. 1.

FIG. 2 shows an integrated circuit 1 that is different from the integrated circuit shown in FIG. 1 in that the first region 4 is n-doped and the second regions 31₁-31ₙ₊₁ are p-doped. Thus, in each voltage limiting structure, the cathodes of the two Avalanche or Zener diodes are formed by the first region 4, and the anodes are formed by the associated second regions. The polarities of the diodes shown in FIG. 2 reflect this. In this example, of the first and second load nodes 12, 13 the load node that is connected to the first region 4 is the one with the higher electrical potential. Thus, pn-junctions between the second regions 31₁-31ₙ and the first region 4 are reverse biased and a current flow from the vias 5₁-5ₙ₊₁ into the first semiconductor layer 110 is prevented. For example, if the transistors 2₁-2ₙ are n-type transistor devices, in operation of the integrated structure, the second load node 13 has the higher electrical potential and, therefore, is connected to the first region 4. Such connection is schematically illustrated in dashed lines in FIG. 2.

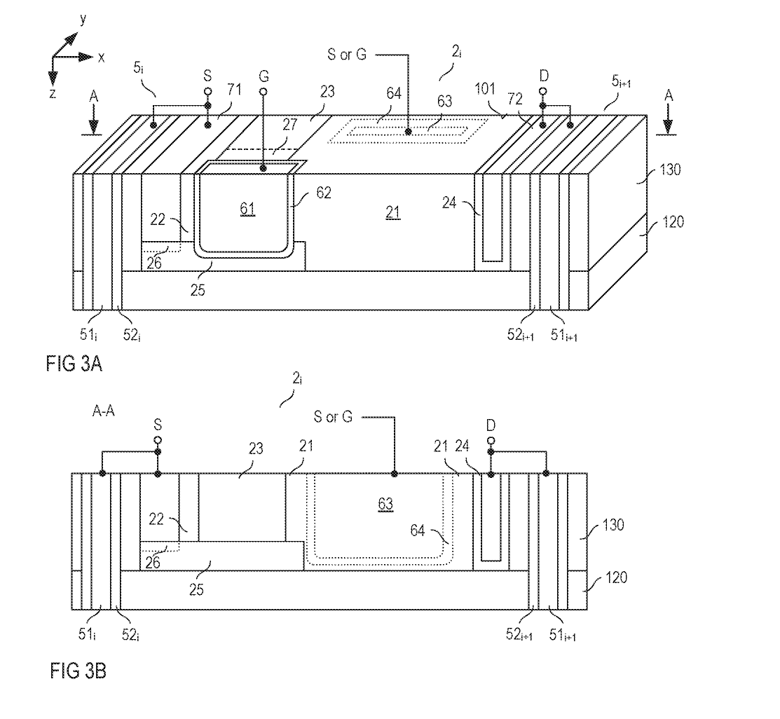

FIG. 3A shows a perspective sectional view and FIG. 3B shows a vertical cross sectional view of one embodiment of one transistor 2ᵢ of the plurality of transistors 2₁-2ₙ. This transistor 2ᵢ represents an arbitrary one of the plurality of transistors 2₁-2ₙ. Each of the transistors 2₁-2ₙ may be implemented as shown in FIGS. 3A-3B. However, it is also possible to implement the transistors such that they have different topologies. In FIGS. 3A-3B, reference characters 5ᵢ and 5ᵢ₊₁ denote the two vias between which the load path of the transistor 2ᵢ is connected. For example, if transistor 2ᵢ represents the first transistor 2₁, then these two vias are vias 5₁ and 5₂ shown in FIGS. 1 and 2. In the following, via 5ᵢ will be referred to as first via, and via 5ᵢ₊₁ will be referred to as second via.

Referring to FIGS. 3A-3B, the transistor 2ᵢ includes active device regions integrated in the second semiconductor layer 130. In the present embodiment, those active device regions include a drift region 21, a source region 22, a body region 23 and a drain region 24. The source region 22 and the drain region 24 are spaced apart in a first lateral direction x of the second semiconductor layer 130. This first lateral direction x is the direction in which the first via 5ᵢ and the second via 5ᵢ₊₁ are spaced apart. The body region 23 separates the source region 22 from the drift region 21, and the drift region 21 separates the body region 23 from the drain region 24. According to one example, the doping concentrations of the source region 22 and the drain region 24 are selected from a range of between 1E19 cm⁻³ m and 1E21 c⁻³, the doping concentration of the body region 23 is selected from a range of between 5E16 cm⁻³ and 1E18 cm⁻³, and the doping concentration of the drift region 21 is selected from a range of between 1E15 cm⁻³ and 1E18 cm⁻³. The doping concentration of the body connection region 25 can be equal to or higher than the doping concentration of the body region 23.

Furthermore, the transistor 2ᵢ includes a gate electrode 61 adjacent the body region 23 and dielectrically insulated from the body region 23 by a gate dielectric 62. In the present embodiment, the gate electrode 61 is arranged in a trench that extends from a first surface 101 of the second semiconductor layer 130 into the second semiconductor layer 130. However, implementing the gate electrode 61 as a trench electrode in a trench of the second semiconductor layer 130 is only an example, Any other type of gate topology may be used as well. For example, the gate electrode 61 can be implemented as a planar electrode above the body region 23 and dielectrically insulated from the body region 23 by the gate dielectric 62.

The gate electrode 61 is connected to the gate node G of the transistor 2ᵢ, or forms the gate node G. The source region 22 is electrically connected to a source electrode 71. This source electrode 71 is connected to the source node S of the transistor 2ᵢ, or forms the source node S. The drain region 24 is electrically connected to a drain electrode 72. This drain electrode 72 is electrically connected to the drain node D or forms the drain node D of the transistor 2ᵢ. Referring to the above, the source node S is connected to the first via 5ᵢ, and the drain node D is connected to the second via 5ᵢ₊₁. Those electrical connections are only schematically shown in FIGS. 3A-3B. For example, these electrical connection can be implemented in a wiring arrangement (not shown in FIGS. 3A-3B) above the surface 101. Those wiring arrangements for implementing electrical interconnections between regions of a semiconductor body are commonly known so that no further explanations are required in this regard.

In the embodiment shown in FIGS. 3A-3B, the source electrode 71 and the drain electrode 72 are each implemented as trench electrodes. That is, each of these electrodes 71, 72 is arranged in a trench that extends from the surface 101 into the second semiconductor layer 130. However, this is only an example. According to another embodiment (not shown), the source electrode 71 is arranged on the source region 22 on the surface 101 and/or the drain electrode 72 is arranged on the drain region 24 on the surface 101.

Besides the source region 22, also the body region 23 is electrically connected to the source electrode 71. In the present embodiment, the body region 23 is connected to the source electrode 71 via a connection region 25 located between the body region 23 and the insulation layer 120. The connection region 25 is of the same doping type as the body region 23 and is electrically connected to the source electrode 71. Optionally, the connection region 25 includes a contact region 26 that may have a higher doping concentration than other regions of the connection region 25 and provides for an ohmic contact between the source electrode 71 and the connection ration 25. The connection region 25 adjoins the source electrode 71 in a region between the source electrode 71 and the insulation layer 120. Optionally, the connection region 25, in the first lateral direction x extends below the gate electrode 61 and the gate dielectric 62 to the drift region 21 and forms a pn-junction with the drift region 21. In this example, the connection region 25 and the drift region 21 are part of another voltage limiting structure. For example, if the drift region 21 is n-doped, the connection region 25 is p-doped, and the transistor device 2ᵢ is in the off-state, the pn-junction between the connection region 25 and the drift region 21 is reverse biased when a positive voltage is applied between the drain node D and the source node S. This pn-junction breaks through when the voltage level reaches a threshold level. Such threshold level is dependent on a length of the drift ration 21 between the connection region 25 and the drain region 24, wherein the threshold level decreases as the length decreases (that is, the closer the connection region 25 is to the drain region 24). According to one example, the connection region extends farther in the direction of the drain region 24 than the body region 23. By this, if a voltage higher than the voltage blocking capability of the transistor is applied between the drain node D and the source node S an Avalanche breakthrough occurs at the pn junction between the connection region 25 and the drift region 21 before an Avalanche breakthrough can occur between the drift region 21 and the body ration 23. This is desirable to prevent hot charge carriers from getting into the field electrode dielectric 62 where they may negatively influence the on resistance of the respective transistor.

According to one example, the threshold level of this further voltage limiting structure is lower than the threshold level of associated voltage limiting structure below the insulation layer 120. In this case, the further voltage limiting structure essentially limits (clamps) the voltage between the drain and source nodes D, S while the voltage limiting structure below the insulation layer essentially protects the insulation layer 120 from high voltages by generating a depletion region in the first semiconductor layer 110, in the way explained with reference to FIG. 1.

The source region 22, the drift region 21 and the drain region 24 have the same doping type (n-type or p-type), and the body region 23 has a doping type complementary to the doping type of the source region 22, the drift region 21 and the drain region 24. The connection region 25 and the optional contact region 26 have the same doping type as the body region 23. In an n-type MOSFET, the source region 22, the drift region 21 and the drain region 24 are n-doped, and the body region 23 is p-doped. In a p-type MOSFET, the individual active regions have a doping type that is complementary to the respective doping type in the n-type MOSFET. The transistor 2ᵢ can be implemented as an enhancement MOSFET or as a depletion MOSFET. In an enhancement MOSFET, the body region 23 adjoins the gate dielectric 62. In this type of MOSFET, the gate electrode 61 serves to control an inversion channel in the body region 23 between the source region 22 and the drift region 21. In a depletion MOSFET, there is a channel region 27 of the same doping type as the source region 22 and the drift region 21 along the gate dielectric 62 between the source region 22 and the drift region 21. Such channel ration is illustrated in dotted lines in FIG. 3A. In this type of MOSFET, the gate electrode 61 serves to control a conducting channel in the channel region 27, whereas the transistor 2ᵢ is in the off-state when the gate electrode 61 is driven such that the channel region 27 is completely depleted of charge carriers. When the transistor 2ᵢ is an enhancement MOSFET, it is in the off-state when the gate electrode 61 is driven such that there is no inversion channel in the body region 23 along the gate dielectric.

Optionally, the transistor 2ᵢ includes a field electrode 63 in the drift region 21. The field electrode 63 is dielectrically insulated from the drift region 21 by a field electrode dielectric 64. The field electrode 63 is either electrically connected to the source node S of the transistor 2ᵢ or the gate node G of the transistor 2ᵢ. Referring to FIGS. 3A-3B, the field electrode 63, like the gate electrode 61, may be arranged in a trench extending from the surface 101 into the second semiconductor layer 130.

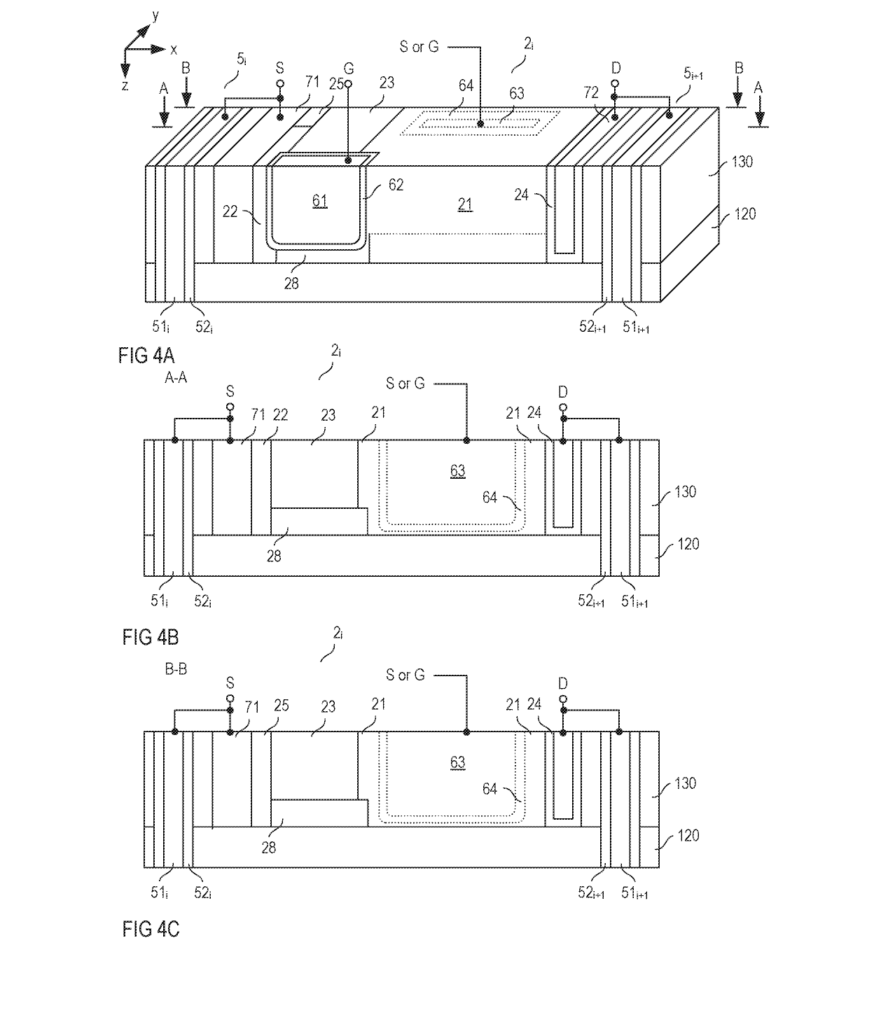

FIG. 4A shows a perspective sectional view and FIGS. 4B-4C show vertical cross sectional views of a transistor 2ᵢ according to another embodiment. The transistor 2ᵢ shown in FIGS. 4A-4B is a modification of the transistor 2ᵢ shown in FIGS. 3A-3B. In the transistor 2ᵢ shown in FIGS. 4A-4C, the connection region 25 that electrically connects the body region 23 to the source electrode 71 is arranged between the source electrode 71 and the body region 23 in the first lateral direction x, and adjoins the source region 22 in a second lateral direction y perpendicular to the first lateral direction x. In this embodiment, the source electrode 71, the source region 22, and the connection region 25 may extend from the first surface 101 down to the insulation layer 120. Optionally, there is a semiconductor region 28 of the same doping type as the body region 23 that extends along the insulation layer 120 from the source region 22 and the connection region 25, respectively, to the drain region 24. Like the connection region 25 shown in FIGS. 3A-3B this region 28 forms a pn junction with the drift region and is part of another voltage limiting structure. The region 28 may extend farther in the direction of the drain region 24 than the body region 23.

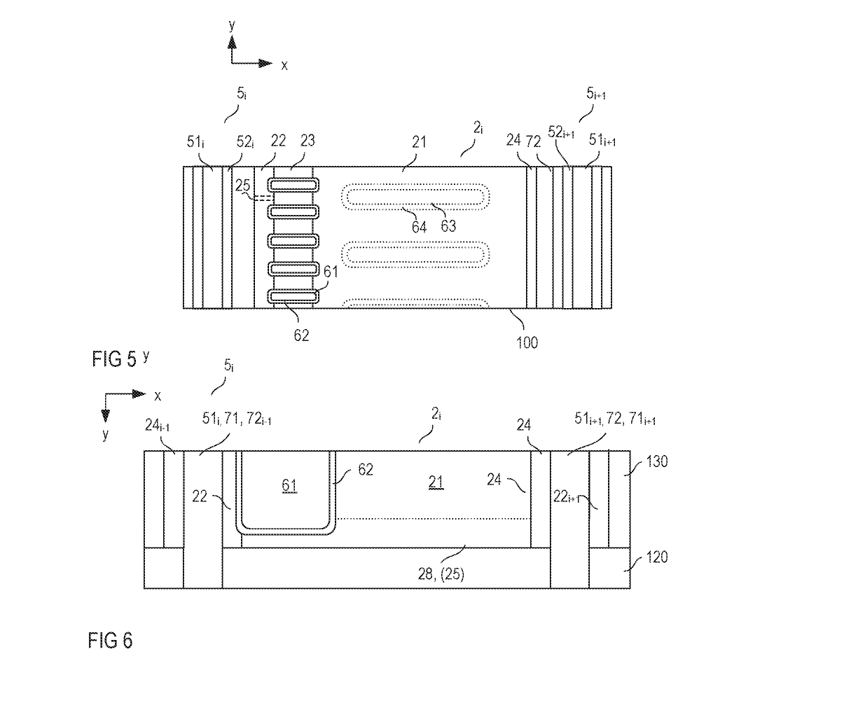

Referring to FIG. 5, which shows a top view of the semiconductor device 2ᵢ according to one of the embodiments shown in FIGS. 3A-3B or 4A-4C, the transistor 2ᵢ may include a plurality of gate electrodes 61, with each of these gate electrodes 61 being adjacent the body region 23 and dielectrically insulated from the body region 23 by a gate dielectric 62. Each of these gate electrodes 61 is electrically connected to the gate node, which is not shown in FIG. 5. These gate electrodes 61 are spaced apart in the second lateral direction y so that there are sections of the body region 23 between the individual gate electrodes 61. Dependent on the type of transistor 2ᵢ, there may or may not be channel regions 72 along the gate dielectrics 61. However, these channel regions are not shown in FIG. 5. Furthermore, the transistor 2ᵢ may include a plurality of field electrodes 63 each dielectrically insulated from the drift region 21 by a field electrode dielectric 64. The individual field electrodes 63 are either connected to the gate node G or the source node S. However, such electrical connections are not shown in FIG. 5.

FIG. 6 shows a vertical cross sectional view of a transistor 2ᵢ according to another embodiment, The embodiment shown in FIG. 6 is based on the embodiments shown in FIGS. 3A-3B and 4A-4C and is different from these embodiments in that there are two electrodes extending from the surface 101 through the second semiconductor layer 130 and the insulation layer 120 into the first semiconductor layer 110, with the latter not being shown in FIG. 6. One of these electrodes at the same time forms the core 51ᵢ of the first via 5ᵢ, the source electrode 71, and a drain electrode 72ᵢ₋₁ of a first adjacent transistor. From this first adjacent transistor, only the drain region 24ᵢ₋₁, which adjoins the drain electrode 72ᵢ₋₁, is shown. The second electrode, at the same time forms the core 51ᵢ₋₁ of the second via 5ᵢ₊₁, the drain electrode 72 and a source electrode 71ᵢ₊₁ of a second adjacent transistor. From this second adjacent transistor only the source region 22ᵢ₊₁ is shown. The source electrode 71 may be connected to the body region (which is out of view in FIG. 6) in the way explained with reference to FIGS. 4A-4C, that is, there may be a connection region between the source electrode 71 and the body region in the first lateral direction x.

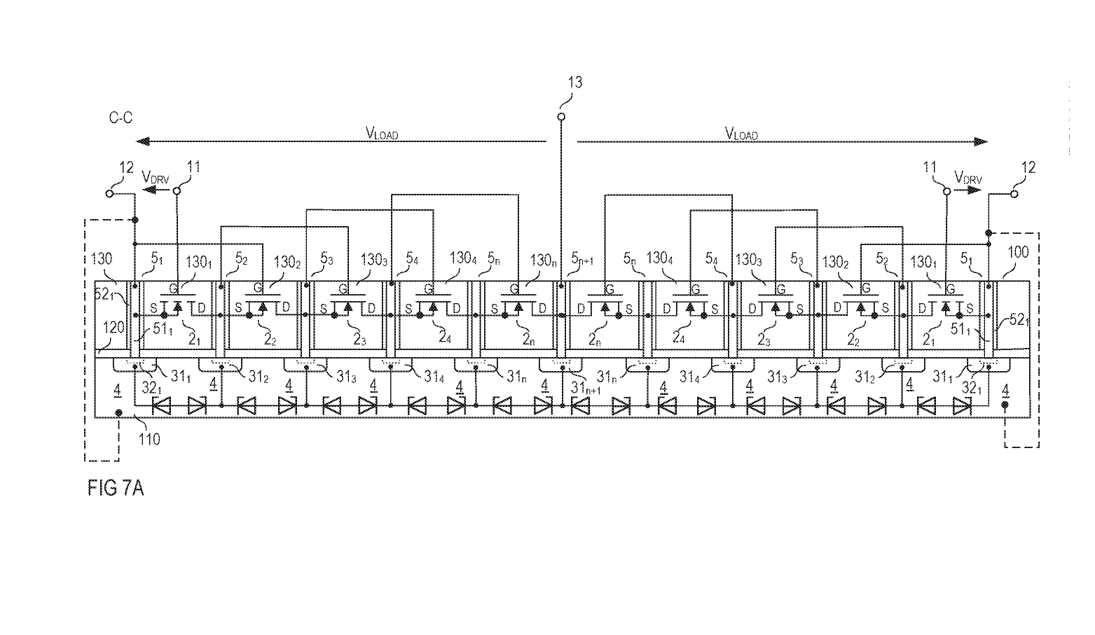

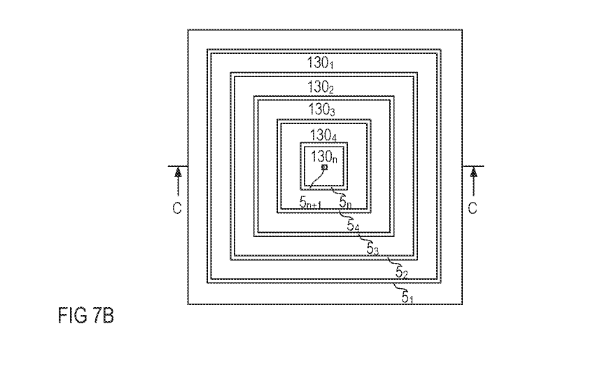

FIGS. 7A-7B show a modification of the integrated circuit 1 shown in FIG. 1. FIG. 7A shows a vertical cross sectional view of the integrated circuit, and FIG. 7B shows a top view In this integrated circuit, semiconductor regions 130₁-130ₙ that include the transistors 2₁-2ₙ are concentric regions arranged around one via 5ₙ, which will be referred to as innermost via in the following. In this example, the innermost via is that via 5 that is connected to the second load node 13. This, however, is only an example. In another example (not shown) via 5₁ connected to the first load node 12 is the innermost via. Referring to FIG. 7B, not only the semiconductor regions 130₁-130ₙ but also the other vias 5₁-5₄ are concentrically arranged around the innermost via 5ₙ. via.

In the integrated circuit shown in FIGS. 7A-7B, the electrical potential of the first and second semiconductor layer 110, 130 in regions outside the structure with the concentric regions equals the electrical potential of that load node that is connected to the outermost via 5₁ and the first region 4, respectively. In the example shown in FIG. 7A the first load node 12 is connected to the outermost via 5₁ and the first region 4, respectively. For example, if the transistors 2₁-2ₙ are n-type devices the electrical potential of the first load node 12 is the lowest electrical potential in the integrated circuit. In this case, the electrical potential increases towards the innermost via 5ₙ when the integrated circuit 1 is in the off-state. In other configurations the outermost via 5₁ and the first region 4 can be connected to that load node that has the highest potential. In this case, the electrical potential decreases towards the innermost via 5ₙ when the integrated circuit 1 is in the off-state.

Although the vias 5₁-5ₙ are drawn to include a collar in the example shown in FIG. 7A this is only an example. The vias 5₁-5ₙ could also be implemented without a collar as explained with reference to FIG. 6. In FIG. 7B, the vias 5₁-5ₙ are only schematically illustrated so that a collar, if there is one, is not shown. Furthermore, although the semiconductor regions 130₁-130ₙ and the vias 5₁-5₄ are drawn as rectangular rings this is only an example. Other shapes such as circular rings, elliptical rings, or polygonal rings may be used as well.

As used herein, the terms “having”, “containing”, “including”, “comprising” and the like are open-ended terms that indicate the presence of stated elements or features, but do not preclude additional elements or features. The articles “a”, “an” and “the” are intended to include the plural as well as the singular, unless the context clearly indicates otherwise.

With the above range of variations and applications in mind, it should be understood that the present invention is not limited by the foregoing description, nor is it limited by the accompanying drawings. Instead, the present invention is limited only by the following claims and their legal equivalents.

What is claimed is:

1. An integrated circuit, comprising:
a semiconductor body comprising a first semiconductor layer, an insulation layer on the first semiconductor layer, and a second semiconductor layer on the insulation layer;
a plurality of transistors each comprising a load path and a control node, wherein the load paths are connected in series to form a transistor series circuit, and wherein the plurality of transistors are at least partially integrated in the second semiconductor layer; and
a voltage limiting structure connected in parallel with the load path of one of the plurality of transistors, wherein the voltage limiting structure is integrated in the first semiconductor layer and is connected to the one of the plurality of transistors through two electrically conducting vias extending through the insulation layer.

2. The integrated circuit of claim 1, further comprising a further voltage limiting structure integrated in the second semiconductor layer and connected in parallel with the load path of one of the plurality transistors.

3. The integrated circuit of claim 1, further comprising a plurality of voltage limiting structures, wherein each of the plurality of voltage limiting structures is connected in parallel with the load path of one of the plurality of transistors.

4. The integrated circuit of claim 3,
wherein the integrated circuit includes n transistor devices, n voltage limiting structures and n+1 electrically conducting vias, and
wherein n−1 of the n+1 electrically conducting vias are each connected to two voltage limiting structures.

5. The integrated circuit of claim 4, wherein the two voltage limiting structures are voltage limiting structures connected in parallel with two transistors that are adjacent in the transistor series circuit.

6. The integrated circuit of claim 1,
wherein the first semiconductor layer has a basic doping of a first doping type,
wherein the voltage limiting structure comprises two doped regions of a second doping type complementary to the first doping type,
wherein each of the two doped regions is connected to one of the two electrically conducting vias.

7. The integrated circuit of claim 1, wherein at least one of the two electrically conducting vias includes an electrically conducting core and an electrically insulating collar that insulates the core from the first semiconductor layer.

8. The integrated circuit of claim 1, wherein each of the plurality of transistors comprises:
a source region, a body region, a drift region and a drain region, wherein the body region is arranged between the source region and the drift region, the drift region is arranged between the body region and the drain region, and the source region and the drain region are spaced apart in a lateral direction of the first semiconductor layer; and
a gate electrode adjacent the body region and dielectrically insulated from the body region by a gate dielectric.

9. The integrated circuit of claim 8, wherein the gate electrode is arranged in a trench of the first semiconductor layer.

10. The integrated circuit of claim 8, wherein each of the plurality of transistor devices further comprises:
a source electrode electrically connected to the source region; and
a drain electrode electrically connected to the drain region.

11. The integrated circuit of claim 8, further comprising:
a further voltage limiting structure integrated in the second semiconductor layer and connected in parallel with the load path of one of the plurality transistors; and
a region of the same doping type as the body region and electrically coupled to the source electrode,
wherein the further voltage limiting structure comprises the drift region and the region of the same doping type as the body region.

12. The integrated circuit of claims 11, wherein the region of the same doping type as the body region extends farther in the direction of the drain region than the body region.

13. The integrated circuit of claim 11, wherein the source electrode is arranged in a first trench of the first semiconductor layer and the source electrode is arranged in a second trench of the first semiconductor layer.

14. The integrated circuit of claim 13,
wherein the source electrode extends through the insulation layer and forms one of the two electrically conducting vias, and
wherein the drain electrode extends through the insulation layer and forms another one of the two electrically conducting vias.

15. The integrated circuit of claim 11, wherein at least one of the plurality of transistors further comprises:
a field electrode dielectrically insulated from the drift region by a field electrode dielectric,
wherein the field electrode is electrically connected to one of the gate electrode and the source electrode.

16. The integrated circuit of claim 8, wherein at least one of the plurality of transistors comprises a plurality of spaced apart gate electrodes that are electrically connected to a common gate node.

17. The integrated circuit of claim 1, further comprising:
an integrated circuit control node, an integrated circuit first load node and an integrated circuit second load node,
wherein the load paths of the plurality of transistors are connected in series between the integrated circuit load nodes, and
wherein the control node of one of the plurality of transistors is connected to the integrated circuit control node.

18. The integrated circuit of claim 17, wherein the one of the plurality of transistors is an enhancement transistors and others of the plurality of transistors are depletion transistors.
